(19) United States
(12) Patent Application Publication
(10) Pub. No.: US 2004/0144316 A1
(43) Pub. Date: Jul. 29, 2004

(54) Apparatus for processing a substrate

(76) Inventors: Soo-Woong Lee, Suwon-city (KR); Jung-Sung Hwang, Suwon-city (KR); Kun-Hyung Lee, Suwon-city (KR)

Correspondence Address: LEE & STERBA, P.C., Suite 2000, 1101 Wilson Boulevard, Arlington, VA, 22209, US

(21) Appl. No.: 10/704,667

(22) Filed: Nov. 12, 2003

(30) Foreign Application Priority Data
Jan. 24, 2003 (KR) 2003-4848

(51) Int. Cl. C23C 16/00

(52) U.S. Cl. 118/719

(57) ABSTRACT

An apparatus for processing a substrate includes a load port for supporting a container for receiving a plurality of substrates, a substrate processing module for processing the substrate transferred from the container, a substrate transfer module, including a substrate transfer chamber connecting the load port with the substrate processing module and a substrate transfer robot disposed in the substrate transfer chamber for transferring the substrate, a fan filter unit connected to the substrate transfer chamber for supplying air, a differential pressure gauge connected to the substrate transfer chamber for measuring a differential pressure between internal and external pressures of the substrate transfer chamber, and a pressure adjustment means for exhausting air supplied into the substrate transfer chamber and for adjusting a flow rate of air being exhausted from the substrate transfer chamber according to the differential pressure so that the internal pressure is maintained higher than the external pressure.

### BACKGROUND OF THE INVENTION

1. Field of the Invention

The present invention relates to an apparatus for processing a substrate. More particularly, the present invention relates to a substrate processing apparatus having a substrate transfer module for transferring a substrate from a container for receiving a plurality of substrates to a substrate processing module for processing the substrate.

2. Description of the Related Art

Generally, semiconductor devices are manufactured through a three-step process. First, a fabrication process is performed for forming electronic circuits on a silicon wafer used as a semiconductor substrate. Second, an electrical die sorting (EDS) process is performed for inspecting electrical characteristics of the semiconductor devices formed on the semiconductor substrate. Third, a packaging process is performed for packaging the semiconductor devices in epoxy resins and individuating the semiconductor devices.

The fabrication process may include a deposition process for depositing a layer on the substrate, a chemical mechanical polishing (CMP) process for planarizing a surface of the layer, a photolithography process for forming photoresist pattern on the layer, an etching process for forming an electrical pattern using the photoresist pattern, an ion implantation process for implanting a predetermined ion into a predetermined portion of the semiconductor substrate, a cleaning process for removing impurities, an inspection process for inspecting the surface of the semiconductor substrate on which the layer or pattern is formed, or other similar processes.

These processes are performed under high vacuum conditions in order to prevent contamination of the semiconductor substrate. To provide the high vacuum conditions, a substrate processing apparatus includes a load lock chamber maintained under low vacuum conditions, a processing chamber where the process is performed, and a substrate transfer chamber for transferring the semiconductor substrate between the load lock chamber and the processing chamber.

A substrate processing apparatus for performing some process (for example, a deposition process or a dry etching process) on a semiconductor substrate having a 300 mm diameter includes a load lock chamber, a substrate transfer chamber and a processing chamber. The substrate processing apparatus may further include a load port for supporting a front opening unified pod (FOUP) and a substrate transfer module for transferring the semiconductor substrate between the load port and the load lock chamber.

The substrate transfer module includes a substrate transfer chamber for connecting the load port and the load lock chamber and a substrate transfer robot for transferring the semiconductor substrate between the FOUP and the load lock chamber.

A fan filter unit (FFU) is connected to an upper portion of substrate transfer chamber. The fan filter unit provides an interior of the substrate transfer chamber with clean air for preventing contamination of the semiconductor substrate being transferred by the substrate transfer robot.

A plurality of exhaust holes is formed through a bottom panel of the substrate transfer chamber for exhausting the clean air provided by the fan filter unit out of the substrate transfer chamber or a clean room, in which the substrate processing apparatus is provided.

When a pressure of the interior of the substrate transfer chamber is lower than a pressure of the clean room, the air in the clean room may flow back into the substrate transfer chamber, so that the semiconductor substrate received in the FOUP and the semiconductor substrate being transferred by the substrate transfer robot may be contaminated. Therefore, it is preferable to maintain the internal pressure of the substrate transfer chamber higher than the pressure of the clean room.

The pressure of the clean room, in which the semiconductor device manufacturing process is performed, is generally a positive pressure (i.e., higher than atmospheric pressure). When the air condition of the clean room is unstable, however, particles that exist in the clean room may flow into the interior of the substrate transfer chamber. Namely, when the air condition of the clean room is changed abruptly, or when the pressure of the clean room is higher than that of the substrate transfer chamber, particles may flow into the substrate transfer chamber. Further, when a side panel is opened for maintenance of a substrate transfer robot disposed in the interior of the substrate transfer chamber or for maintenance of a door opener for opening a door of the FOUP, particles may enter the substrate transfer chamber. The particles entering the substrate transfer chamber and remaining in the substrate transfer chamber contaminate the semiconductor substrate, thereby deteriorating the reliability and productivity of the semiconductor device.

### SUMMARY OF THE INVENTION

In an effort to overcome at least some of the above problems, the present invention provides an apparatus for processing a substrate that evenly maintains a differential pressure between a pressure of a clean room and a pressure of an interior of a substrate transfer chamber at a predetermined level.

According to an embodiment of the present invention, an apparatus for processing a substrate includes a load port for supporting a container for receiving a plurality of substrates, a substrate processing module for processing the substrate transferred from the container, a substrate transfer module, including a substrate transfer chamber connecting the load port with the substrate processing module and a substrate transfer robot disposed in the substrate transfer chamber for transferring the substrate, a fan filter unit connected to the substrate transfer chamber for supplying clean air into the substrate transfer chamber, a differential pressure gauge connected to the substrate transfer chamber for measuring a differential pressure between an internal pressure and an external pressure of the substrate transfer chamber, and a pressure adjustment means for exhausting the clean air supplied into the substrate transfer chamber and for adjusting a flow rate of the clean air being exhausted from the substrate transfer chamber according to the differential pressure measured by the differential pressure gauge so that the internal pressure is maintained higher than the external pressure.

In an embodiment of the present invention, the pressure adjustment means includes a base panel for dividing the substrate transfer chamber into an upper portion and a lower portion, wherein the substrate is transferred in the upper portion, the clear air is supplied into the upper portion, the base panel has a plurality of first exhaust holes for exhausting the clear air from the upper portion into the lower portion, and the clear air supplied into the upper portion is exhausted to an outside of the substrate transfer chamber through the lower portion, a moving panel disposed parallel over the base panel, and having a plurality of second exhaust holes for exhausting the clean air from the upper portion into the lower portion, and a driving part for driving the moving panel in order to adjust the flow rate of the clean air being exhausted from the substrate transfer chamber. A guiding member disposed on the base panel for supporting and guiding the moving panel may be further included.

The apparatus may further include a pair of covers for preventing clean air from flowing into the space between the base panel and the moving panel, the pair of covers interposed between the base panel and the moving panel and extending downwardly from front and back portions of a lower surface of the moving panel relative to a direction of motion of the moving panel.

The apparatus may further include a control unit for controlling operation of the driving part to move the moving panel to misalign centers of the second exhaust holes and centers of the first exhaust holes when the differential pressure is higher than a predetermined value, and to move the moving panel to align centers of the second exhaust holes with centers of the first exhaust holes when the differential pressure is lower than the predetermined value.

Preferably, a bottom panel of the substrate transfer chamber has an opening for exhausting clean air exhausted into the lower portion through the second exhaust holes of the moving panel and the first exhaust holes of the base panel.

In an embodiment of the present invention, the base panel has a circular opening and the moving panel has an oval opening, so that the substrate transfer robot, which is supported by the bottom panel of the substrate transfer chamber, extends upwardly through the circular opening and the oval opening. Preferably, the oval opening extends in a direction parallel to the direction of motion of the moving panel.

In another embodiment of the present invention, the pressure adjustment means includes a base panel for dividing the substrate transfer chamber into an upper portion and a lower portion, wherein the substrate is transferred in the upper portion, the clear air is supplied into the upper portion, the base panel has a plurality of first exhaust holes for exhausting the clear air from the upper portion into the lower portion, and the clear air supplied into the upper portion is exhausted to an outside of the substrate transfer chamber through the lower portion, a moving panel slidably disposed on an upper surface of the base panel, and having a plurality of second exhaust holes for exhausting the clean air from the upper portion into the lower portion, and a driving part for driving the moving panel in order to adjust the flow rate of the clean air being exhausted from the substrate transfer chamber.

In still another embodiment of the present invention, the pressure adjustment means includes a base panel for dividing the substrate transfer chamber into an upper portion and a lower portion, wherein the substrate is transferred in the upper portion, the clear air is supplied into the upper portion, the base panel has a plurality of first exhaust holes for exhausting the clear air from the upper portion into the lower portion, and the clear air supplied into the upper portion is exhausted to an outside of the substrate transfer chamber through the lower portion, a moving panel slidably disposed on a lower surface of the base panel, and having a plurality of second exhaust holes for exhausting the clean air from the upper portion into the lower portion, and a driving part for driving the moving panel in order to adjust the flow rate of the clean air being exhausted from the substrate transfer chamber.

The present invention may further include a connection member positioned on an edge of the upper surface of the moving panel to connect the moving panel to the driving part.

The substrate transfer robot may be disposed on an upper surface of the base panel.

In yet another embodiment of the present invention, a bottom panel of the substrate transfer chamber has a plurality of first exhaust holes, and the pressure adjustment means includes a moving panel slidably disposed on an upper surface or a lower surface of the bottom panel, and having a plurality of second exhaust holes for exhausting clean air, and a driving part for driving the moving panel in order to adjust the flow rate of the clean air being exhausted from the substrate transfer chamber.

An embodiment of the present invention may include a bracket protruding horizontally inwardly from a side panel of the substrate transfer chamber for supporting the substrate transfer robot.

An embodiment of the present invention may include a load lock chamber interposed between the substrate processing module and the substrate transfer module.

According to yet still another embodiment of the present invention, an apparatus for processing a substrate includes a load port for supporting a container for receiving a substrate, a substrate processing module for processing the substrate transferred from the container, a substrate transfer module having a substrate transfer chamber connecting the load port with the substrate processing module and a substrate transfer robot disposed in the substrate transfer chamber for transferring the substrate, a fan filter unit connected to the substrate transfer chamber for supplying clean air into the substrate transfer chamber, a base panel for dividing the substrate transfer chamber into an upper portion and a lower portion, wherein the substrate is transferred in the upper portion, the clear air is supplied into the upper portion, the base panel has a plurality of first exhaust holes for exhausting the clear air from the upper portion into the lower portion, and the clear air supplied into the upper portion is exhausted to an outside of the substrate transfer chamber through the lower portion, a differential pressure gauge connected to the substrate transfer chamber for measuring a differential pressure between an internal pressure in the upper portion and an external pressure of the substrate transfer chamber, a moving panel disposed parallel to the base panel, and having a plurality of second exhaust holes for exhausting the clean air from the upper portion into the lower portion, and a control unit for driving the moving panel in order to adjust a flow rate of the clean air being exhausted from the substrate transfer chamber according to the differential pressure measured by the differential pressure gauge so that the internal pressure is maintained higher than the external pressure.

In an embodiment of the present invention, a bottom panel of the substrate transfer chamber has an opening for exhausting the clean air from the lower portion of the substrate transfer chamber.

In an embodiment of the present invention, the moving panel is slidably disposed on an upper surface or a lower surface of the base panel, and the substrate transfer robot is supported on a bottom panel of the substrate transfer chamber and extends upwardly through the moving and base panels.

An embodiment of the present invention may include a bracket protruding horizontally inwardly from a side panel of the substrate transfer chamber for supporting the substrate transfer robot.

In an embodiment of the present invention, the moving panel is slidably disposed on a lower surface of the base panel, and the substrate transfer robot is supported on an upper surface of the base panel.

### BRIEF DESCRIPTION OF THE DRAWINGS

The above and other features and advantages of the present invention will become more apparent to those of ordinary skill in the art by describing in detail preferred embodiments thereof with reference to the attached drawings in which:

FIG. 1 illustrates a cross-sectional view schematically showing a substrate processing apparatus according to a first embodiment of the present invention;

FIG. 2 illustrates a plan view schematically showing the substrate processing apparatus as shown in FIG. 1;

FIG. 3 illustrates a partially cutaway view in perspective of a pressure adjustment unit as shown in FIG. 1;

FIGS. 4A and 4B illustrate cross-sectional views showing the operation of the pressure adjustment unit as shown in FIG. 1;

FIG. 5 illustrates a cross-sectional view schematically showing a substrate processing apparatus according to a second embodiment of the present invention;

FIG. 6 illustrates a partially cutaway view in perspective of a pressure adjustment unit as shown in FIG. 5;

FIGS. 7A and 7B illustrate cross-sectional views schematically showing the operation of the pressure adjustment unit as shown in FIG. 5;

FIG. 8 illustrates a cross-sectional view schematically showing a substrate processing apparatus according to a third embodiment of the present invention;

FIG. 9 illustrates a cross-sectional view schematically showing a substrate processing apparatus according to a fourth embodiment of the present invention;

FIG. 10 illustrates a cross-sectional view schematically showing a substrate processing apparatus according to a fifth embodiment of the present invention;

FIG. 11 illustrates a partially cutaway view in perspective of a pressure adjustment unit as shown in FIG. 10;

FIG. 12 illustrates a plan view schematically showing the pressure adjustment unit as shown in FIG. 10.

### DETAILED DESCRIPTION OF THE INVENTION

Korean Patent Application No. 2003-4848, filed Jan. 24, 2003, and entitled: “Apparatus for Processing a Substrate,” is incorporated by reference herein in its entirety.

The present invention will now be described more fully hereinafter with reference to the accompanying drawings, in which preferred embodiments of the invention are shown. The invention may, however, be embodied in different forms and should not be construed as limited to the embodiments set forth herein. Rather, these embodiments are provided so that this disclosure will be thorough and complete, and will fully convey the scope of the invention to those skilled in the art. Like reference numerals refer to like elements throughout.

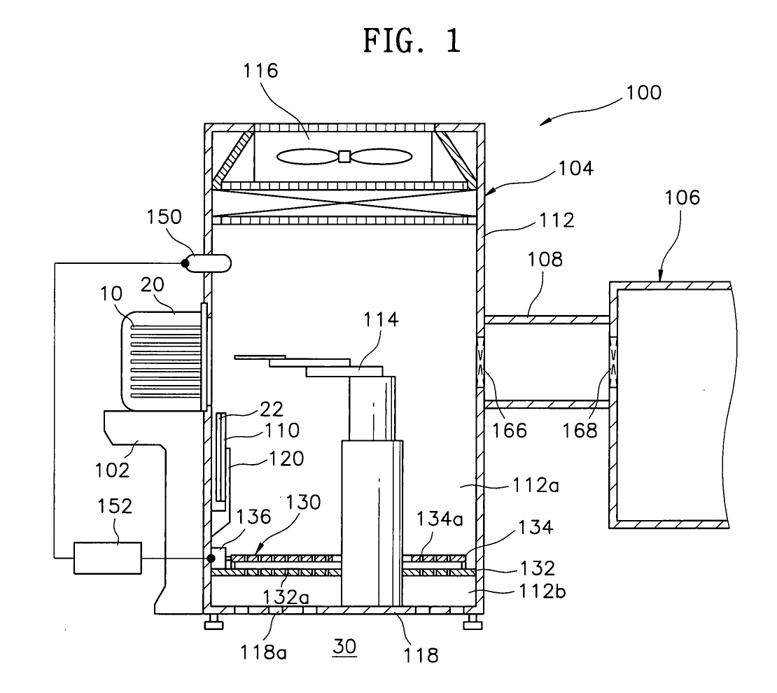

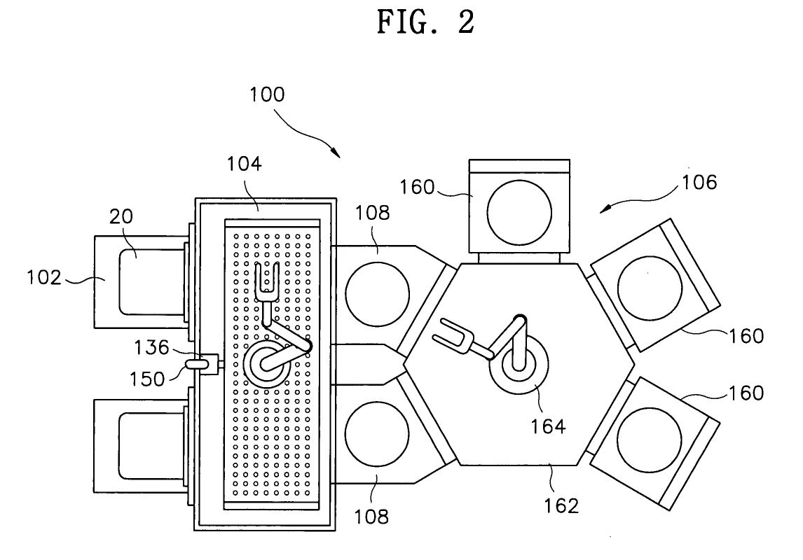

FIG. 1 illustrates a cross-sectional view schematically showing a substrate processing apparatus according to a first embodiment of the present invention. FIG. 2 illustrates a plan view schematically showing the substrate processing apparatus as shown in FIG. 1.

Referring to FIGS. 1 and 2, a substrate processing apparatus 100 performs a process, such as a deposition process for depositing a layer on a semiconductor substrate, a dry etching process for forming an electrical pattern with a layer formed on the semiconductor substrate, or another similar process. The substrate processing apparatus 100 includes a load port 102, a substrate transfer module 104, a substrate processing module 106, and a load lock chamber 108.

The load port 102 is connected to the substrate transfer module 104 and supports a container for receiving a plurality of semiconductor substrates 10. A front opening unified pod (FOUP) 20 may be used as the container. Although not shown in detail, the load port 102 supports the FOUP 20 and brings the FOUP 20 into contact with a door 110 of the substrate transfer module 104.

The substrate transfer module 104 includes a first substrate transfer chamber 112 for connecting the load port 102 with the load lock chamber 108. A first substrate transfer robot 114 is disposed in the first substrate transfer chamber 112 for transferring a semiconductor substrate 10 between the FOUP 20 supported by the load port 102 and the load lock chamber 108.

A filter fan unit 116 is connected to the first substrate transfer chamber 112 for supplying the first substrate transfer chamber 112 with clean air. A plurality of openings 118a is formed through a bottom panel 118 of the first substrate transfer chamber 112 for exhausting the clean air supplied from the fan filter unit 116 to a clean room 30.

In this first embodiment of the present invention, the first substrate transfer robot 114 is disposed on the bottom panel 118 of the first substrate transfer chamber 112. A door opener 120 is connected to the door 110 of the substrate transfer module 104 for opening the door 22 of the FOUP 20.

A door opening and closing unit (not shown) is installed in the door 110 of the substrate transfer module 104 for opening and closing the door 22 of the FOUP 20.

The substrate processing module 106 is connected to the substrate transfer module 104 through the load lock chamber 108. The substrate processing module 106 includes processing chambers 160 for processing the semiconductor substrate 10, a second substrate transfer chamber 162 for connecting the load lock chamber 108 with the processing chamber 160, a second substrate transfer robot 164 disposed in the second substrate transfer chamber 162 for transferring the semiconductor substrate 10 between the load lock chamber 108 and the processing chamber 160.

A first slit valve 166 connects the first substrate transfer chamber 112 to the load lock chamber 108. A second slit valve 168 connects the load lock chamber 108 to the second substrate transfer chamber 162. A third slit valve (not shown) connects the second substrate transfer chamber 162 to the processing chamber 160.

A differential pressure gauge 150 is connected to the first substrate transfer chamber 112. The differential pressure gauge 150 measures a pressure of the interior of the first substrate transfer chamber 112, a pressure of the clean room 30, and a differential pressure therebetween.

The substrate processing apparatus 100 has a pressure adjustment unit 130 for adjusting the pressure of the interior of the first substrate transfer chamber 112. The pressure adjustment unit 130 has a base panel 132 for exhausting the clean air supplied from the fan filter unit 116, a moving panel 134 and a driving part 136 for driving the moving panel 134.

The base panel 132 is horizontally positioned in the first substrate transfer chamber 112 to divide an internal space of the first substrate transfer chamber 112 into an upper portion 112a and a lower portion 112b. The upper portion 112a is disposed adjacent to the fan filter unit 116, and the lower portion 112b is disposed adjacent to the bottom panel 118 of the first substrate transfer chamber 112.

The upper portion 112a is defined by the fan filter unit 116, side panels of the first substrate transfer chamber 112 and the base panel 132. The lower portion 112b is defined by the base panel 132, side panels of the first substrate transfer chamber 112 and the bottom panel 118.

A plurality of first exhaust holes 132a is formed through the base panel 132, so that the clean air of the upper portion 112a may be discharged through the lower portion 112b. The moving panel 134 is disposed over the base panel 132 and is capable of movement parallel to the base panel 132. A plurality of second exhaust holes 134a is formed through the moving panel 134, so that clean air in the upper portion 112a may be discharged through the lower portion 112b. The fan filter unit 116 supplies the upper portion 112a with clean air. The clean air supplied into the upper portion 112a is discharged into the lower portion 112b through the first exhaust holes 132a and the second exhaust holes 134a. The clean air of the lower portion 112b is discharged into the clean room 30 through the openings 118a.

The driving part 136 is disposed on the base panel 132 and connected to the moving panel 134. The driving part 136 drives the moving panel 134 to adjust the internal pressure of the first substrate transfer chamber 112.

The differential pressure gauge 150 is connected to a control unit 152. A differential pressure signal produced by the differential pressure gauge 150 is sent to the control unit 152. The control unit 152 is also connected to the driving part 136. The control unit 152 controls operation of the driving part 136 according to the differential pressure signal so that the differential pressure between the internal pressure and the external pressure of the first substrate transfer chamber 112 is maintained at a predetermined level. At that time, the internal pressure of the first substrate transfer chamber 112 is a pressure in the upper portion of the first substrate transfer chamber 112.

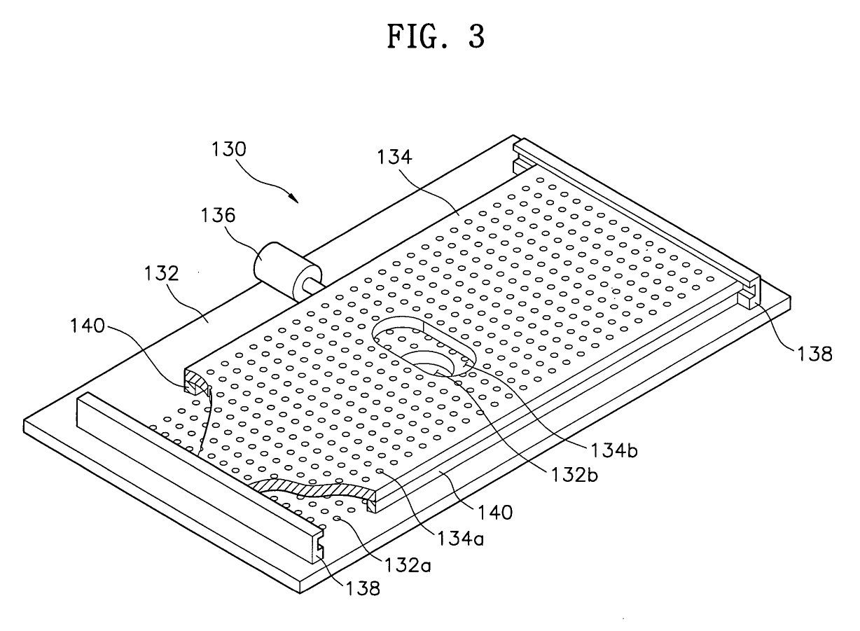

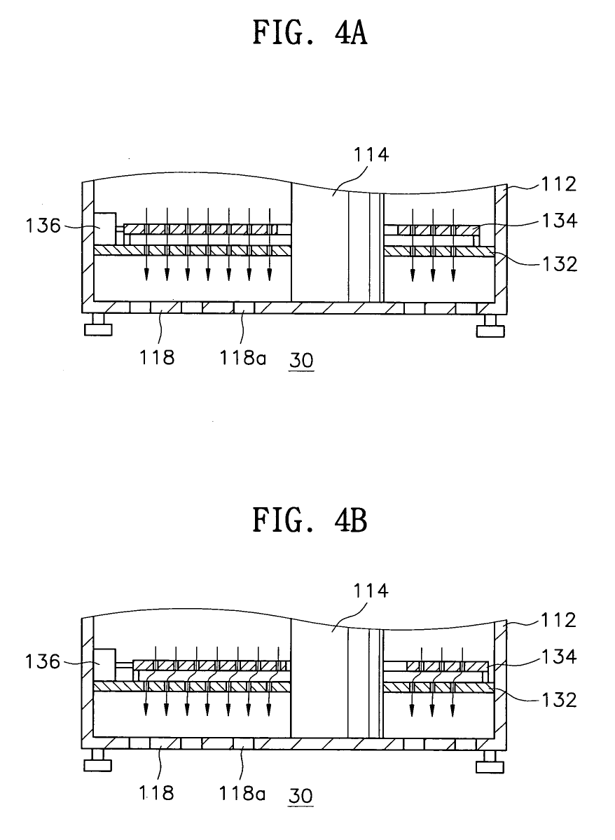

FIG. 3 illustrates a partially cutaway view in perspective of the pressure adjustment unit 130 as shown in FIG. 1. FIGS. 4A and 4B illustrate cross-sectional views showing the operation of the pressure adjustment unit 130 as shown in FIG. 1.

Referring to FIG. 3, the pressure adjustment unit 130 includes the base panel 132, the moving panel 134 and the driving part 136. The base panel 132 has a rectangular shape and includes the plurality of first exhaust holes 132a. A pair of guiding members 138 is disposed parallel to the direction of motion of the moving panel 134 on the base panel 132 to support and guide the moving panel 134.

The moving panel 134 has a rectangular shape and includes the plurality of second exhaust holes 134a. The moving panel 134 is positioned horizontally over the base panel 132 and is connected to the driving part 136. A pair of covers 140 is interposed between the base panel 132 and the moving panel 134 for preventing clean air from flowing into the space between the base panel 132 and the moving panel 134. The pair of covers 140 extend downwardly from front and back portions of a lower surface of the moving panel 134 relative to direction of motion of the moving panel 134.

A circular opening 132b is formed through the base panel 132, through which the first substrate transfer robot 114 is supported by the bottom panel 118 and extends upwardly through the circular opening 132b. An oval opening 134b is formed through the moving panel 134, and the first substrate transfer robot 114 extend upwardly through the oval opening 134b. The circular opening 132b is formed at a central portion of the base panel 132, and the oval opening 134b is similarly formed at a central portion of the moving panel 134. The oval opening 134b extends in a direction parallel to the direction of motion of the moving panel 134 so that the moving panel 134 is able to move without being obstructed by the first substrate transfer robot 114.

A hydraulic cylinder and a pneumatic cylinder may be used as the driving part 136. However, the driving part 136 may be embodied in various driving device and a power transmission device. For example, an assembly of a motor and a power transmission device of a ball screw type may be used as the driving part 136.

Referring to FIG. 4A, if the differential pressure between the pressure of the interior of the first substrate transfer chamber 112 and the pressure of the clean room 30 is higher than a predetermined level, the driving part 136 drives the moving panel 134, so that centers of the second exhaust holes 134a of the moving panel 134 align with centers of the first exhaust holes 132a of the base panel 132. Alternately, referring to FIG. 4B, if the differential pressure between the pressure of the interior of the first substrate transfer chamber 112 and the pressure of the clean room 30 is lower than the predetermined level, the driving part 136 drives the moving panel 134, so that centers of the second exhaust holes 134a of the moving panel 134 misalign with centers of the first exhaust holes 132a of the base panel 132.

Preferably, the differential pressure is maintained positive to prevent particles in the clean room 30 from entering the interior of the first substrate transfer chamber 112.

When the second exhaust holes 134a of the moving panel 134 align with the first exhaust holes 132a of the base panel 132, the flow resistance of the clean air is reduced. Therefore, the flow rate of exhausted clean air is increased and the differential pressure between the internal and external pressures is decreased. Alternately, when the second exhaust holes 134a of the moving panel 134 are misaligned with the first exhaust holes 132a of the base panel 132, the flow resistance of the clean air is increased. Therefore, the flow rate of exhausted clean air is decreased and the differential pressure between the internal and external pressures is increased.

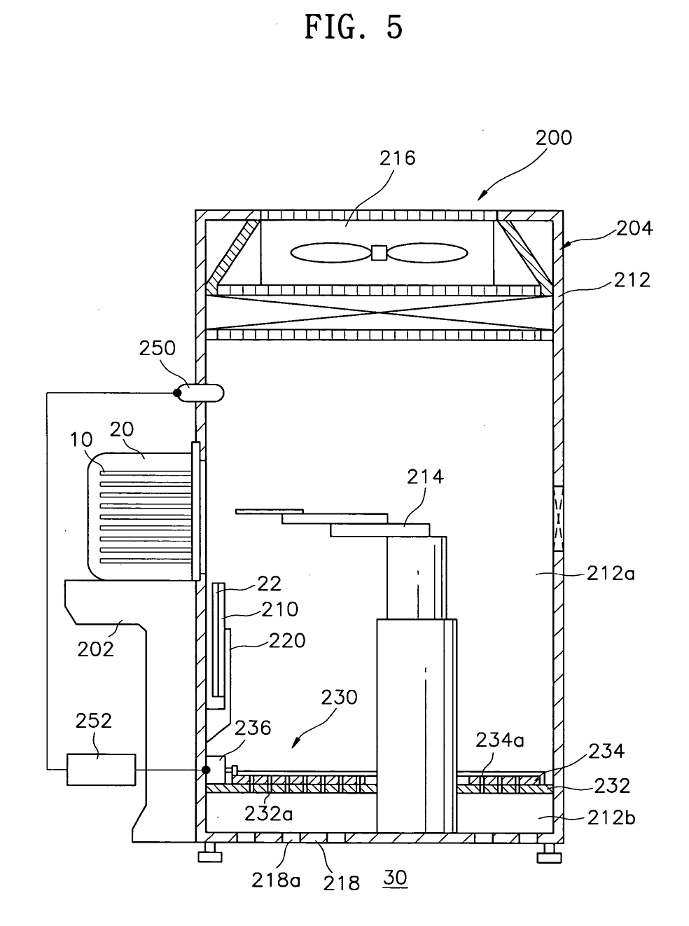

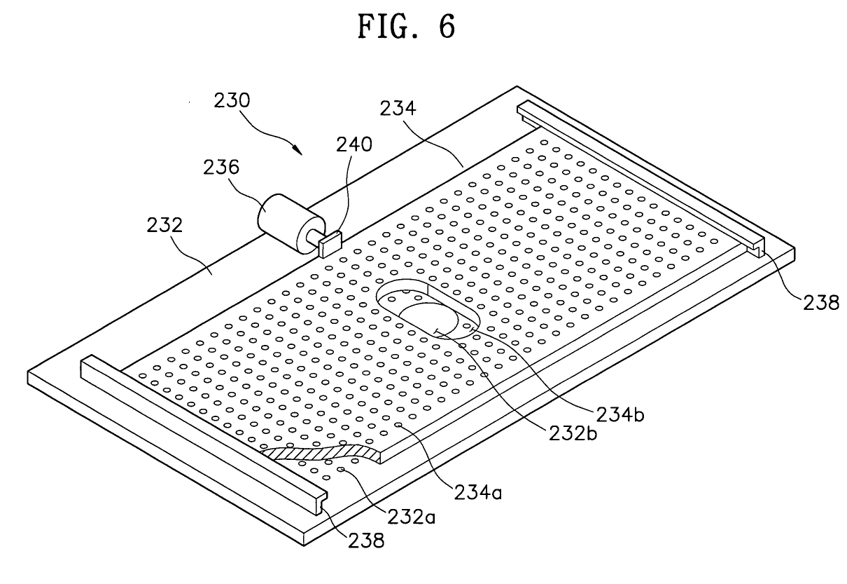

FIG. 5 illustrates a cross-sectional view schematically showing a substrate processing apparatus according to a second embodiment of the present invention. FIG. 6 illustrates a partially cutaway view in perspective of a pressure adjustment unit as shown in FIG. 5.

Referring to FIGS. 5 and 6, a substrate processing apparatus 200 according to the second embodiment of the present invention includes a load port 202 for supporting the FOUP 20 for receiving a substrate 10, a substrate processing module (not shown, refer to FIGS. 1 and 2 for illustration) for processing the semiconductor substrate 10, a substrate transfer module 204 for transferring the semiconductor substrate 10 received in the FOUP 20, and load lock chamber (not shown, refer to FIGS. 1 and 2 for illustration) interposed between the substrate processing module and the substrate transfer module 204.

The substrate transfer module 204 includes a first substrate transfer chamber 212 interposed between the load port 202 and the load lock chamber, a first substrate transfer robot 214 disposed in the first substrate transfer chamber 212 for transferring the semiconductor substrate 10 between the load port 202 and the load lock chamber, a door opener 220 for opening and closing the door 22 of the FOUP 20 in contact with the door 210 of the first substrate transfer chamber 212, a fan filter unit 216 for supplying the interior of the first substrate transfer chamber 212 with clean air, a differential pressure gauge 250 for measuring a differential pressure between an internal pressure of the interior of the first substrate transfer chamber 212 and a pressure of the clean room 30, and a pressure adjustment unit 230 for adjusting the internal pressure of the first substrate transfer chamber 212 in accordance with the differential pressure.

Further detailed descriptions of these elements will be omitted as these elements are sufficiently similar to those already described in connection with the substrate processing apparatus shown in FIGS. 1 and 2.

The pressure adjustment unit 230 includes a base panel 232, a moving panel 234 and a driving part 236 for driving the moving panel 232.

The base panel 232 is positioned in the first substrate transfer chamber 212 and divides an internal space of the first substrate transfer chamber 212 into an upper portion 212a adjacent to the fan filter unit 216 and a lower portion 212b adjacent to a bottom panel 218 of the first substrate transfer chamber 212.

The upper portion 212a is defined by the fan filter unit 216, side panels of the first substrate transfer chamber 212 and the base panel 232. The lower portion 212b is defined by the base panel 232, side panels of the first substrate transfer chamber 212 and the bottom panel 218.

The base panel 232 has a rectangular shape. The moving panel 234 is slidably disposed on an upper surface of the base panel 232.

A pair of guiding members 238 is positioned along a direction of motion of the moving panel 234 on an upper surface of base panel 232 and guides side portions of the moving panel 234. The driving part 236 is positioned on the upper surface of the base panel 232. A connection member 240 is positioned on an edge of the upper surface of the moving panel 234 to connect the moving panel 234 with the driving part 236.

A plurality of first exhaust holes 232a and a plurality of second exhaust holes 234a corresponding to the first exhaust holes 232a are formed through the base panel 232 and the moving panel 234, respectively, to discharge the clean air supplied into the upper portion 212a of the first substrate transfer chamber 212 through the lower portion 212b of the first substrate transfer chamber 212.

A plurality of openings 218a is formed through the bottom panel 218 of the first substrate transfer chamber 212 for discharging the clean air of the lower portion 212b of the first substrate transfer chamber 212 into the clean room 30.

The first substrate transfer robot 214 is supported by the bottom panel 218 of the first substrate transfer chamber 212 through a circular opening 232b of the base panel 232 and an oval opening 234b of the moving panel 234. The oval opening 234b extends in a direction parallel to the direction of motion of the moving panel 234 so that the first substrate transfer robot 214 does not obstruct the movement of the moving panel 234.

The circular opening 232b is formed at a central portion of the base panel 232. The oval opening 234b is similarly formed at a central portion of the moving panel 234.

The differential pressure gauge 250 sends a measured differential pressure signal to a control unit 252, and the control unit 252 controls operation of the driving part 236 according to the measured differential pressure signal. If the measured differential pressure is higher than the predetermined level, the driving part 236 drives the moving panel 234 to increase the flow area of clean air. More specifically, the driving part 236 aligns centers of the second exhaust holes 234a of the moving panel 234 with centers of the first exhaust holes 232a of the base panel 232, so that the flow area of the clean air is increased and the pressure of the interior of the first substrate transfer chamber 212 is decreased. Alternately, if the measured differential pressure is below the predetermined level, the driving part 236 drives the moving panel 234 to decrease the flow area of clean air. More specifically, the driving part 236 misaligns centers of the second exhaust holes 234a of the moving panel 234 with centers of the first exhaust holes 232a of the base panel 232, so that the flow area of the clean air is decreased and the pressure of the interior of the first substrate transfer chamber 212 is increased.

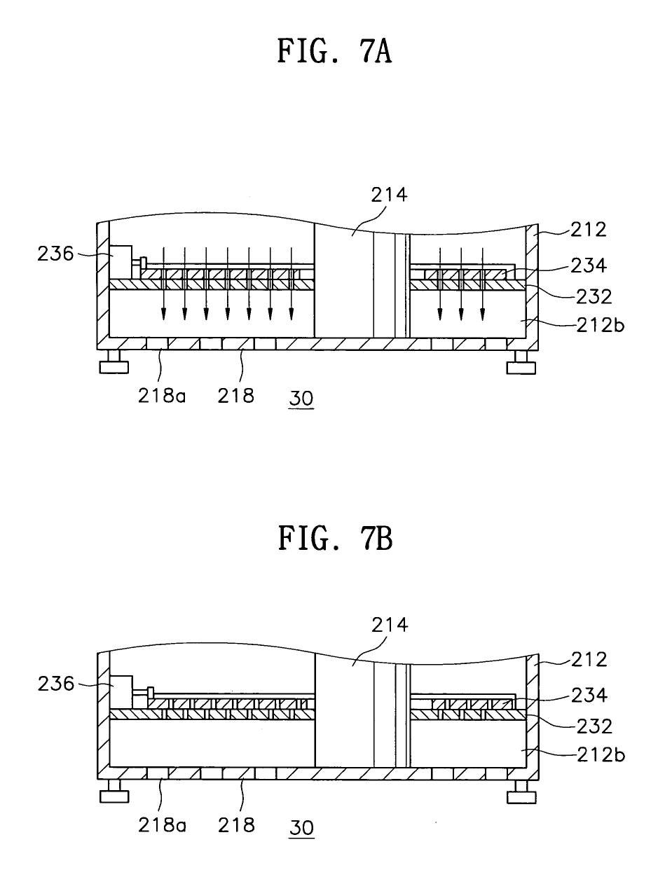

FIGS. 7A and 7B illustrate cross-sectional views schematically showing the operation of the pressure adjustment unit of FIG. 5.

Referring to FIGS. 7A and 7B, when centers of the second exhaust holes 234a of the moving panel 234 align with centers of the first exhaust holes 232a of the base panel 232, the flow rate of the clean air has a maximum value. When the first exhaust holes 232a of the base panel 232 and the second exhaust holes 234a of the moving panel 234 are misaligned, the first and second exhaust holes are sealed, and clean air is not discharged into the lower potion 212b. Therefore, when one panel of the first substrate transfer chamber 212 is opened, the first substrate transfer chamber 212 can be protected effectively from contamination.

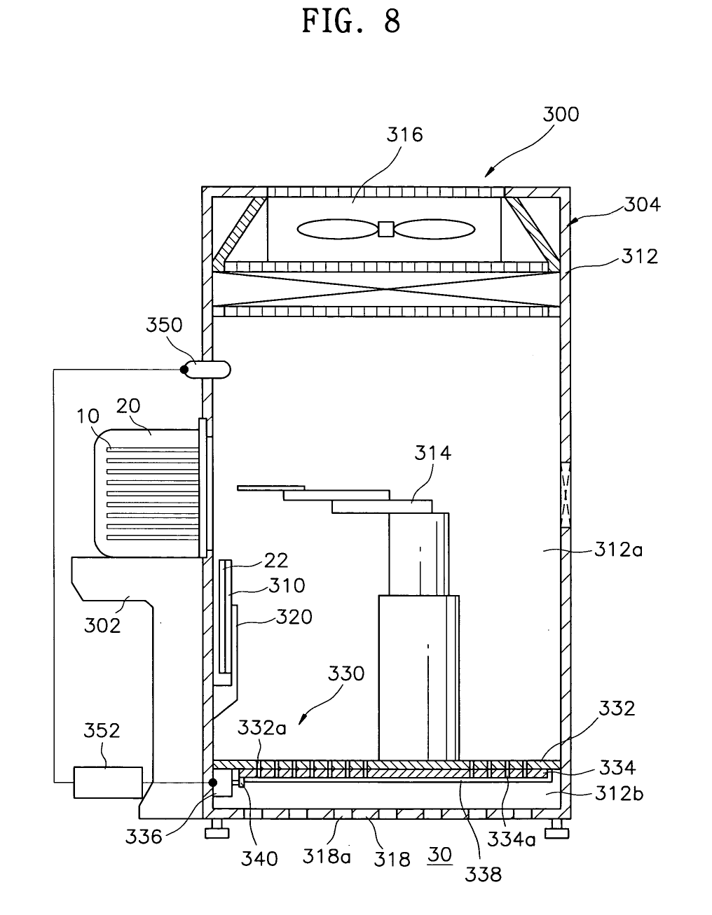

FIG. 8 illustrates a cross-sectional view schematically showing a substrate processing apparatus according to a third embodiment of the present invention.

Referring to FIG. 8, a substrate processing apparatus 300 according to the third embodiment includes a load port 302 for supporting the FOUP 20 for receiving a substrate 10, a substrate processing module (not shown, refer to FIGS. 1 and 2 for illustration) for processing the semiconductor substrate 10, a substrate transfer module 304 for transferring the semiconductor substrate 10 received in the FOUP 20, and a load lock chamber (not shown, refer to FIGS. 1 and 2 for illustration) interposed between the substrate processing module and the substrate transfer module 304.

The substrate transfer module 304 includes a first substrate transfer chamber 312 interposed between the load port 302 and the load lock chamber, a first substrate transfer robot 314 disposed in the first substrate transfer chamber 312 for transferring the semiconductor substrate 10 between the load port 302 and the load lock chamber, a door opener 320 for opening and closing the door 22 of the FOUP 20 in contact with the door 310 of the first substrate transfer chamber 312, a fan filter unit 316 for supplying the interior of the first substrate transfer chamber 312 with clean air, a differential pressure gauge 350 for measuring a differential pressure between an internal pressure and an external pressure of the first substrate transfer chamber 312, and a pressure adjustment unit 330 for adjusting the internal pressure of the interior of the first substrate transfer chamber 312 in accordance with the differential pressure.

The pressure adjustment unit 330 includes a base panel 332, a moving panel 334 and a driving part 336 for driving the moving panel 332.

The base panel 332 is positioned in the first substrate transfer chamber 312 and divides an internal space of the first substrate transfer chamber 312 into an upper portion 312a adjacent to the fan filter unit 316 and a lower portion 312b adjacent to a bottom panel 318 of the first substrate transfer chamber 312. The base panel 332 also supports the first substrate transfer robot 314.

The upper portion 312a is defined by the fan filter unit 316, side panels of the first substrate transfer chamber 312 and the base panel 232. The lower portion 312b is defined by the base panel 232, side panels of the first substrate transfer chamber 312 and the bottom panel 318.

The base panel 332 has a rectangular shape. A moving panel 334 is slidably disposed on a lower surface of the base panel 332.

A pair of guiding members 338 is positioned on the lower surface base panel 332. The direction of the pair of guiding members 338 is parallel to the direction of motion of the moving panel 334, and the pair of guiding members 338 supports and guides side portions of the moving panel 334. The driving part 336 is positioned on the lower surface of the base panel 332. A connection member 340 is positioned on an edge of the lower surface of the moving panel 334 to connect the moving panel 334 with the driving part 336.

Reference numerals 318a, 332a, 334a and 352 indicate openings in the bottom panel 318, first exhaust holes in the base panel 332, second exhaust holes in the moving panel 334, and a control unit, respectively.

Further detailed descriptions of these elements will be omitted as these elements are sufficiently similar to those already described in connection with the substrate processing apparatus according to the first and second embodiments as shown in FIGS. 1, 2, 5 and 6.

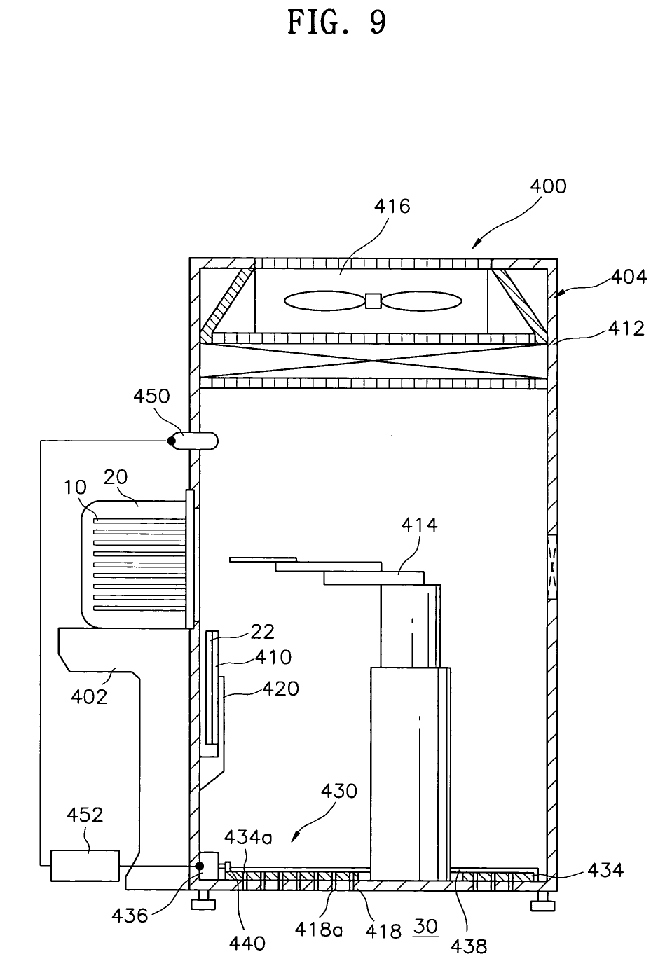

FIG. 9 illustrates a cross-sectional view schematically showing a substrate processing apparatus according to a fourth embodiment of the present invention.

Referring to FIG. 9, a substrate processing apparatus 400 according to a fourth embodiment includes a load port 402 for supporting the FOUP 20 for receiving a semiconductor substrate 10, a substrate processing module (not shown, refer to FIGS. 1 and 2 for illustration) for processing the semiconductor substrate 10, a substrate transfer module 404 for transferring the semiconductor substrate 10 received in the FOUP 20, and load lock chamber (not shown, refer to FIGS. 1 and 2 for illustration) interposed between the substrate processing module and the substrate transfer module 404.

The substrate transfer module 404 includes a first substrate transfer chamber 412 interposed between the load port 402 and the load lock chamber, a first substrate transfer robot 414 disposed in the first substrate transfer chamber 412 for transferring the semiconductor substrate 10 between the load port 402 and the load lock chamber, a door opener 420 for opening and closing the door 22 of the FOUP 20 in contact with a door 410 of the first substrate transfer chamber 412, a fan filter unit 416 for supplying the interior of the first substrate transfer chamber 412 with clean air, a differential pressure gauge 450 for measuring a differential pressure between an internal pressure of the interior of the first substrate transfer chamber 412 and an external pressure of the outside of the first substrate transfer chamber, and a pressure adjustment unit 430 for adjusting the internal pressure of the first substrate transfer chamber 412 in accordance with the differential pressure.

A bottom panel 418 of the first substrate transfer chamber 412 supports the first substrate transfer robot 414. A plurality of a first exhaust holes 418a is formed through the bottom panel 418 for discharging clean air supplied by the fan filter unit 416 into a clean room 30.

A pressure adjustment unit 430 includes a moving panel 434, which has a plurality of second exhaust holes 434a corresponding to the first exhaust holes 418a, and is slidably disposed on an upper surface of the bottom panel 418, and a driving part 436 for driving the moving panel 434. In FIG. 9, though the moving panel 434 is disposed on the upper surface of the bottom panel 418, the moving panel 434 may be disposed on a lower surface of the bottom panel 418.

A pair of guiding members 438 is positioned on the upper surface of bottom panel 418. The direction of the pair of guiding members 438 is parallel to the direction of motion of the moving panel 434, and the pair of guiding members 438 supports and guides side portions of the moving panel 434. The driving part 436 is positioned on the upper surface of the bottom panel 418. A connection member 440 is positioned on an edge of the upper surface of the moving panel 434 for connecting the moving panel 434 with the driving part 436.

Further detailed descriptions of a control unit 452 for controlling operation of the driving part 436 and other elements will be omitted as these elements are sufficiently similar to those already described in connection with the substrate processing apparatus according to the first and second embodiments as shown in FIGS. 1, 2, 5 and 6.

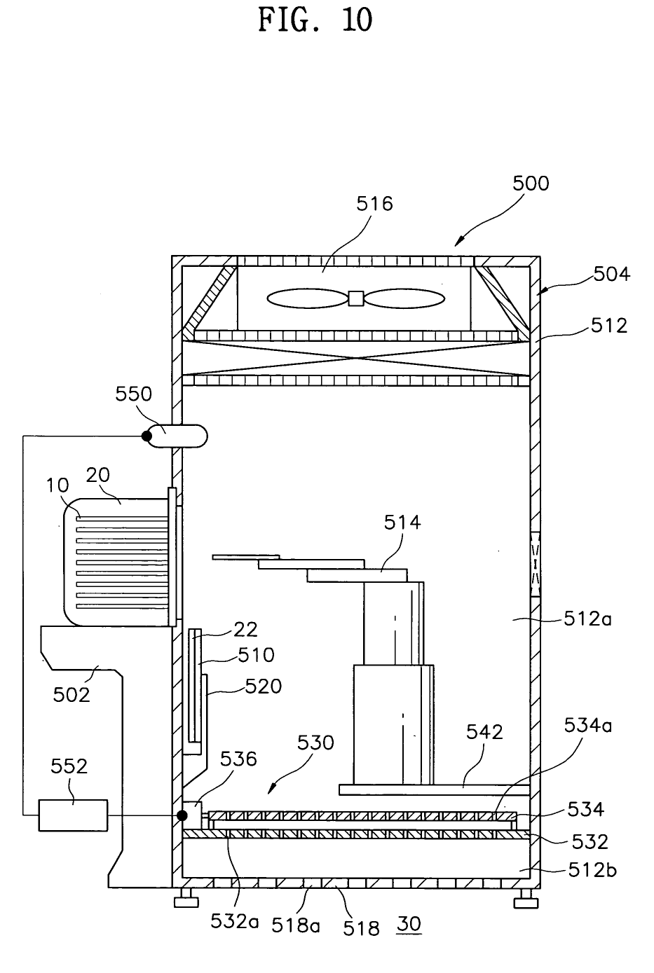

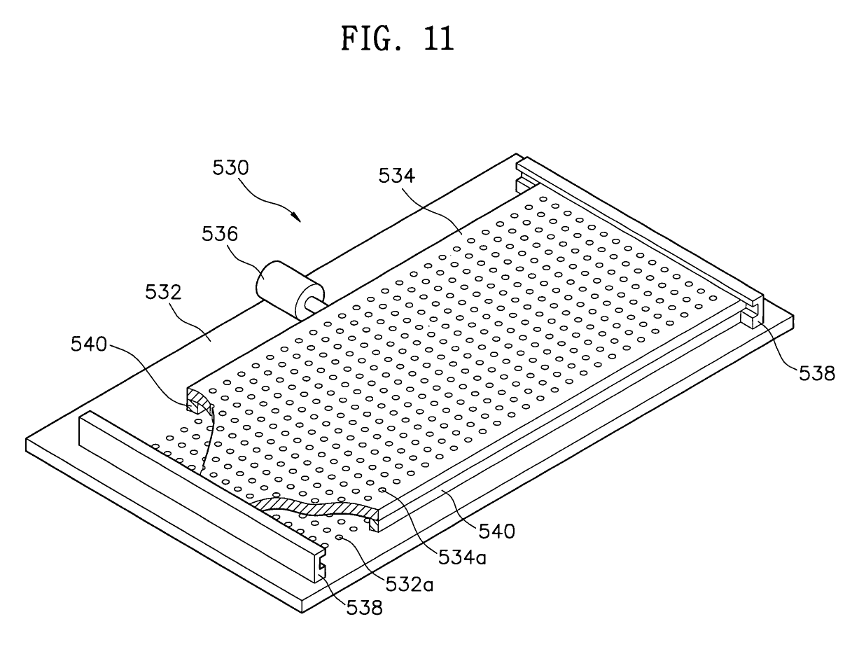

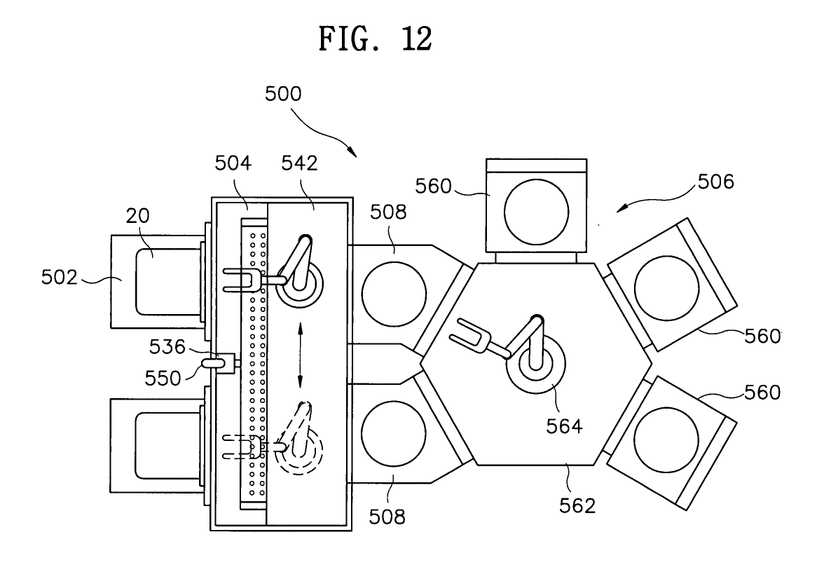

FIG. 10 illustrates a cross-sectional view schematically showing a substrate processing apparatus according to a fifth embodiment of the present invention. FIG. 11 illustrates a partially cutaway view in perspective of a pressure adjustment unit as shown in FIG. 10. FIG. 12 illustrates a plan view schematically showing the pressure adjustment unit as shown in FIG. 10.

Referring to FIGS. 10 to 12, a substrate processing apparatus 500 according to a fifth embodiment includes a load port 502 for supporting the FOUP 20 for receiving a semiconductor substrate 10, a substrate processing module 506 for processing the semiconductor substrate 10, a substrate transfer module 504 for transferring the semiconductor substrate 10 received in the FOUP 20, and a load lock chamber 508 interposed between the substrate processing module 506 and the substrate transfer module 504.

The substrate transfer module 504 includes a first substrate transfer chamber 512 interposed between the load port 502 and the load lock chamber 508, a first substrate transfer robot 514 disposed in the first substrate transfer chamber 512 for transferring the semiconductor substrate 10 between the load port 502 and the load lock chamber 508, a door opener 520 for opening and closing the door 22 of the FOUP 20 in contact with a door 510 of the first substrate transfer chamber 512, a fan filter unit 516 for supplying the interior of the first substrate transfer chamber 512 with clean air, a differential pressure gauge 550 for measuring a differential pressure between a pressure of the interior of the first substrate transfer chamber 512 and the pressure of the clean room 30, and a pressure adjustment unit 530 for adjusting the pressure of the interior of the first substrate transfer chamber 512 in accordance with the differential pressure.

The pressure adjustment unit 530 includes a base panel 532, a moving panel 534 and a driving part 536 for driving the moving panel 534.

The base panel 532 is positioned in the first substrate transfer chamber 512 and divides an internal space of the first substrate transfer chamber 512 into an upper portion 512a adjacent to the fan filter unit 516 and a lower portion 512b adjacent to a bottom panel 518 of the first substrate transfer chamber 512. The upper portion 512a is defined by the fan filter unit 516, side panels of the first substrate transfer chamber 512 and the base panel 532. The lower portion 512b is defined by the base panel 532, side panels of the first substrate transfer chamber 512 and the bottom panel 518.

The base panel 532 has a rectangular shape. The moving panel 534 is movably disposed over the base panel 532. A pair of guiding members 538 is positioned on an upper surface of the base panel 532. The direction of the pair of guiding members 538 is parallel to the direction of motion of the moving panel 534. A pair of covers 540 is attached on a lower surface of the moving panel 534 perpendicular to the pair of guiding members 538, so that the pair of covers 540 and the pair of guiding members 538 form a rectangle for preventing clean air from flowing into the space between the base panel 532 and the moving panel 534. The driving part 536 for driving the moving panel 534 is disposed on the upper surface of the base panel 532.

A bracket 542 protrudes horizontally inwardly from one of the side panels of the first substrate transfer chamber 512 for supporting the first substrate transfer robot 514. The first substrate transfer robot 514 is positioned on the bracket 542 to be able to move along the bracket 542, as shown in FIG. 12.

A plurality of openings 518a in the bottom panel 518, a plurality of first exhaust holes 532a in the base panel 532, a plurality of second exhaust holes 534a in the moving panel 534, a control unit 552, a processing chamber 560, a second substrate processing chamber 562 and a second substrate transfer robot 564 are sufficiently similar to those of the substrate processing apparatus according to the first embodiment of the present invention shown in FIGS. 1 and 2 that a further detailed description thereof will be omitted.

According to the above-described substrate processing apparatus, the differential pressure of the internal and external pressures of the substrate transfer chamber can be evenly maintained at a predetermined level. Therefore, particles in the clean room are prevented from entering the substrate transfer chamber. When one side panel of the substrate transfer chamber is opened for maintenance of the substrate transfer module, the substrate transfer chamber is protected from contamination. Further, avoidance of contamination increases the reliability and the productivity of the semiconductor device.

Preferred embodiments of the present invention have been disclosed herein and, although specific terms are employed, they are used and are to be interpreted in a generic and descriptive sense only and not for purpose of limitation. Accordingly, it will be understood by those of ordinary skill in the art that various changes in form and details may be made without departing from the spirit and scope of the present invention as set forth in the following claims.

What is claimed is:

1. An apparatus for processing a substrate, comprising:
a load port for supporting a container for receiving a plurality of substrates;
a substrate processing module for processing the substrate transferred from the container;
a substrate transfer module, including a substrate transfer chamber connecting the load port with the substrate processing module and a substrate transfer robot disposed in the substrate transfer chamber for transferring the substrate;
a fan filter unit connected to the substrate transfer chamber for supplying clean air into the substrate transfer chamber;
a differential pressure gauge connected to the substrate transfer chamber for measuring a differential pressure between an internal pressure and an external pressure of the substrate transfer chamber; and
a pressure adjustment means for exhausting the clean air supplied into the substrate transfer chamber and for adjusting a flow rate of the clean air being exhausted from the substrate transfer chamber according to the differential pressure measured by the differential pressure gauge so that the internal pressure is maintained higher than the external pressure.

2. The apparatus as claimed in claim 1, wherein the pressure adjustment means comprises:
a base panel for dividing the substrate transfer chamber into an upper portion and a lower portion, wherein the substrate is transferred in the upper portion, the clear air is supplied into the upper portion, the base panel has a plurality of first exhaust holes for exhausting the clear air from the upper portion into the lower portion, and the clear air supplied into the upper portion is exhausted to an outside of the substrate transfer chamber through the lower portion;
a moving panel disposed parallel over the base panel, and having a plurality of second exhaust holes for exhausting the clean air from the upper portion into the lower portion; and
a driving part for driving the moving panel in order to adjust the flow rate of the clean air being exhausted from the substrate transfer chamber.

3. The apparatus as claimed in claim 2, further comprising:
a guiding member disposed on the base panel for supporting and guiding the moving panel.

4. The apparatus as claimed in claim 2, further comprising:
a pair of covers for preventing clean air from flowing into the space between the base panel and the moving panel, the pair of covers interposed between the base panel and the moving panel and extending downwardly from front and back portions of a lower surface of the moving panel relative to a direction of motion of the moving panel.

5. The apparatus as claimed in claim 2, further comprising:
a control unit for controlling operation of the driving part to move the moving panel to misalign centers of the second exhaust holes and centers of the first exhaust holes when the differential pressure is higher than a predetermined value, and to move the moving panel to align centers of the second exhaust holes with centers of the first exhaust holes when the differential pressure is lower than the predetermined value.

6. The apparatus as claimed in claim 2, wherein a bottom panel of the substrate transfer chamber has an opening for exhausting clean air exhausted into the lower portion through the second exhaust holes of the moving panel and the first exhaust holes of the base panel.

7. The apparatus as claimed in claim 2, wherein the base panel has a circular opening and the moving panel has an oval opening, so that the substrate transfer robot, which is supported by the bottom panel of the substrate transfer chamber, extends upwardly through the circular opening and the oval opening.

8. The apparatus as claimed in claim 7, wherein the oval opening extends in a direction parallel to the direction of motion of the moving panel.

9. The apparatus as claimed in claim 1, wherein the pressure adjustment means comprises:
a base panel for dividing the substrate transfer chamber into an upper portion and a lower portion, wherein the substrate is transferred in the upper portion, the clear air is supplied into the upper portion, the base panel has a plurality of first exhaust holes for exhausting the clear air from the upper portion into the lower portion, and the clear air supplied into the upper portion is exhausted to an outside of the substrate transfer chamber through the lower portion;
a moving panel slidably disposed on an upper surface of the base panel, and having a plurality of second exhaust holes for exhausting the clean air from the upper portion into the lower portion; and
a driving part for driving the moving panel in order to adjust the flow rate of the clean air being exhausted from the substrate transfer chamber.

10. The apparatus as claimed in claim 9, further comprising:
a connection member positioned on an edge of the upper surface of the moving panel to connect the moving panel to the driving part.

11. The apparatus as claimed in claim 1, wherein the pressure adjustment means comprises:
a base panel for dividing the substrate transfer chamber into an upper portion and a lower portion, wherein the substrate is transferred in the upper portion, the clear air is supplied into the upper portion, the base panel has a plurality of first exhaust holes for exhausting the clear air from the upper portion into the lower portion, and the clear air supplied into the upper portion is exhausted to an outside of the substrate transfer chamber through the lower portion;
a moving panel slidably disposed on a lower surface of the base panel, and having a plurality of second exhaust holes for exhausting the clean air from the upper portion into the lower portion; and
a driving part for driving the moving panel in order to adjust the flow rate of the clean air being exhausted from the substrate transfer chamber.

12. The apparatus as claimed in claim 11, wherein the substrate transfer robot is disposed on an upper surface of the base panel.

13. The apparatus as claimed in claim 1, wherein a bottom panel of the substrate transfer chamber has a plurality of first exhaust holes, and the pressure adjustment means comprises:
a moving panel slidably disposed on an upper surface or a lower surface of the bottom panel, and having a plurality of second exhaust holes for exhausting clean air; and
a driving part for driving the moving panel in order to adjust the flow rate of the clean air being exhausted from the substrate transfer chamber.

14. The apparatus as claimed in claim 1, further comprising:
a bracket protruding horizontally inwardly from a side panel of the substrate transfer chamber for supporting the substrate transfer robot.

15. The apparatus as claimed in claim 1, further comprising:
a load lock chamber interposed between the substrate processing module and the substrate transfer module.

16. The apparatus as claimed in claim 1, wherein the container is a front opening unified pod (FOUP) having a door.

17. The apparatus as claimed in claim 16, further comprising:
a door opener for opening and closing the door of the front opening unified pod.

18. An apparatus for processing a substrate, comprising:
a load port for supporting a container for receiving a substrate;
a substrate processing module for processing the substrate transferred from the container;
a substrate transfer module having a substrate transfer chamber connecting the load port with the substrate processing module and a substrate transfer robot disposed in the substrate transfer chamber for transferring the substrate;
a fan filter unit connected to the substrate transfer chamber for supplying clean air into the substrate transfer chamber;
a base panel for dividing the substrate transfer chamber into an upper portion and a lower portion, wherein the substrate is transferred in the upper portion, the clear air is supplied into the upper portion, the base panel has a plurality of first exhaust holes for exhausting the clear air from the upper portion into the lower portion, and the clear air supplied into the upper portion is exhausted to an outside of the substrate transfer chamber through the lower portion;
a differential pressure gauge connected to the substrate transfer chamber for measuring a differential pressure between an internal pressure in the upper portion and an external pressure of the substrate transfer chamber;
a moving panel disposed parallel to the base panel, and having a plurality of second exhaust holes for exhausting the clean air from the upper portion into the lower portion; and
a control unit for driving the moving panel in order to adjust a flow rate of the clean air being exhausted from the substrate transfer chamber according to the differential pressure measured by the differential pressure gauge so that the internal pressure is maintained higher than the external pressure.

19. The apparatus as claimed in claim 18, wherein a bottom panel of the substrate transfer chamber has an opening for exhausting the clean air from the lower portion of the substrate transfer chamber.

20. The apparatus as claimed in claim 18, wherein the moving panel is slidably disposed on an upper surface or a lower surface of the base panel, and the substrate transfer robot is supported on a bottom panel of the substrate transfer chamber and extends upwardly through the moving and base panels.

21. The apparatus as claimed in claim 18, further comprising:
a bracket protruding horizontally inwardly from a side panel of the substrate transfer chamber for supporting the substrate transfer robot.

22. The apparatus as claimed in claim 18, wherein the moving panel is slidably disposed on a lower surface of the base panel, and the substrate transfer robot is supported on an upper surface of the base panel.
